(19) United States
(12) Patent Application Publication
(10) Pub. No.: US 2026/0190384 A1
(43) Pub. Date: Jul. 2, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Min-Ti Yang, Kaohsiung City (TW); Ching-Wen Hung, Tainan City (TW); Chun-Hsien Lin, Tainan City (TW); Tai-You Chen, Changhua County (TW)

(73) Assignee: UNITED MICROELECTRONICS CORP., Hsin-Chu City (TW)

(21) Appl. No.: 19/045,577

(22) Filed: Feb. 5, 2025

(30) Foreign Application Priority Data
Dec. 30, 2024 (TW) 113151412

(51) Int. Cl. H10D 30/66; H10D 30/01; H10D 62/832; H10D 64/00

(52) U.S. Cl. CPC H10D 30/66; H10D 30/0291; H10D 62/8325; H10D 64/111

(57) ABSTRACT

A method for fabricating a semiconductor device includes the steps of first forming a gate structure on a substrate, forming a first source electrode adjacent to one side of the gate structure, forming a second source electrode adjacent to another side of the gate structure, forming a first contact plug on the first source electrode, forming a second contact plug on the second source electrode, forming a field plate on the first contact plug and the second contact plug, and forming a drain electrode on a backside of the substrate.

### BACKGROUND OF THE INVENTION

### 1. Field of the Invention

The invention relates to a semiconductor device and fabrication method thereof, and more particularly to a silicon carbide (SiC) metal oxide semiconductor field effect transistor (MOSFET) and method for fabricating the same.

### 2. Description of the Prior Art

Typical power semiconductor device includes insulated gate bipolar transistors (IGBTs) and metal oxide semiconductor field effect transistor (MOSFET) device, within which silicon carbide (SiC) MOSFET has critical breakdown strength, can operate at much higher temperatures, provide higher current density, and support higher switching frequencies.

Although semiconductor device such as SiC MOSFET has the above-mentioned advantages, the gate oxide of silicon carbide (SiC) MOSFET is especially vulnerable on voltage spiking induced on gate bias during operation and electrostatic discharge (ESD) stress because of thinner gate oxide thickness and lower oxide quality. In conventional approach, additional devices may be added for protecting gate oxide from voltage overshot and ESD stress. However, extra space is usually required for accommodating these devices, which ultimately increases cell pitch of the entire device. Since conventional approach for fabricating SiC MOSFETs still exist numerous problems, how to come up with a novel approach for fabricating SiC MOSFETs to resolve the above issues has become an important task in this field.

### SUMMARY OF THE INVENTION

According to an embodiment of the present invention, a method for fabricating a semiconductor device includes the steps of first forming a gate structure on a substrate, forming a first source electrode adjacent to one side of the gate structure, forming a second source electrode adjacent to another side of the gate structure, forming a first contact plug on the first source electrode, forming a second contact plug on the second source electrode, forming a field plate on the first contact plug and the second contact plug, and forming a drain electrode on a backside of the substrate.

According to another aspect of the present invention, a semiconductor device includes a gate structure on a substrate, a first source electrode adjacent to one side of the gate structure, a first contact plug on the first source electrode, a field plate on the first contact plug, and a drain electrode on a backside of the substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-7 illustrate a method for fabricating a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,” “an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,”“upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

Referring to FIGS. 1-7, FIGS. 1-7 illustrate a method for fabricating a semiconductor device according to an embodiment of the present invention. As shown in FIG. 1, a substrate 12 made of semiconductor material is provided, in which the substrate 12 preferably includes a silicon carbide (SiC) substrate. Nevertheless, according to other embodiment of the present invention, the substrate 12 could also include a silicon substrate, an epitaxial silicon substrate, or even a silicon-on-insulator (SOI) substrate, which are all within the scope of the present invention.

Next, from bottom to top a drift region 14 is formed in the substrate 12, a first well region 16 is formed in the drift region 14 adjacent to one side such as left side of a gate structure (not shown) or gate dielectric layer 28 formed afterwards, a second well region 18 is formed in the drift region 14 adjacent to another side such as right side of the gate dielectric layer 28, a first doped region 20 and a second doped region 22 are formed in the first well region 16 adjacent to one side such as left side of the gate dielectric layer 28, a third doped region 24 and a fourth doped region 26 are formed in the second well region 18 adjacent to another side such as right side of the gate dielectric layer 28, and then a gate dielectric layer 28 is formed on the substrate 12, in which the gate dielectric layer 28 is preferably positioned on the surface of the substrate 12 between the second doped region 22 and the third doped region 24.

In this embodiment, the drift region 14 and the first well region 16 and/or second well region 18 preferably include different conductive type, the first doped region 20 and the second doped region 22 include different conductive type, and the third doped region 24 and the fourth doped region 26 include different conductive type. For instance, the drift region 14 preferably includes a N-drift region, each of the first well region 16 and second well region 18 includes a P-well, the first doped region 20 includes a P+ doped region, the second doped region 22 includes a N+ doped region, the third doped region 24 includes a N+ doped region, and the fourth doped region 26 includes a P+ doped region.

After the first doped region 20, the second doped region 22, the third doped region 24, and the fourth doped region 26 are formed, one or more oxidation process such as in-situ steam generation (ISSG) process could be conducted to form a gate dielectric layer 28 made of silicon oxide on the surface of the substrate 12. Preferably, the gate dielectric layer 28 could be disposed to cover all surfaces of the first doped region 20, the second doped region 22, the third doped region 24, and the fourth doped region 26 or could be patterned through an etching process so that the remaining gate dielectric layer 28 only covers part of the second doped region 22, part of the third doped region 24, and the substrate 12 surface between the second doped region 22 and third doped region 24, which are all within the scope of the present invention.

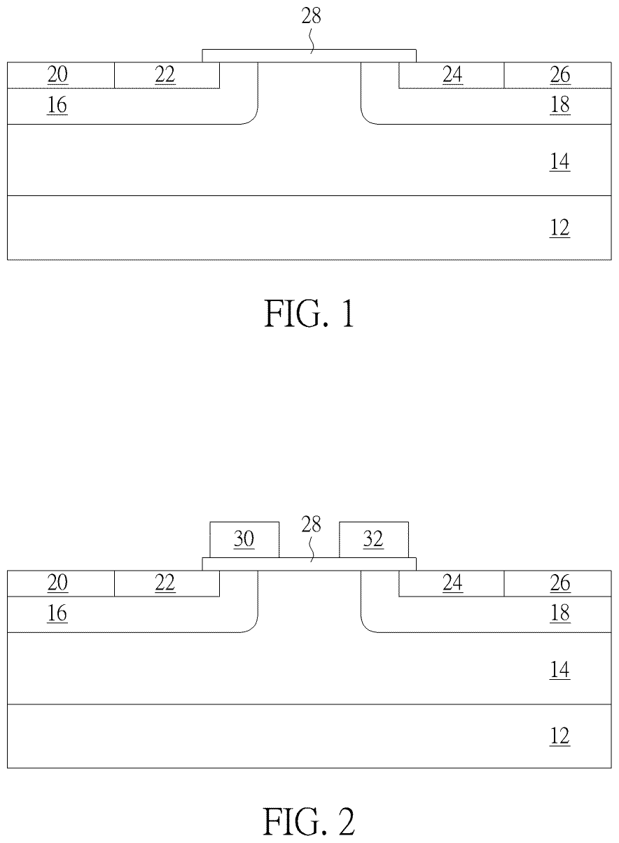

Next, as shown in FIG. 2, at least a gate structure such as gate structures 30, 32 are formed on the gate dielectric layer 28. In this embodiment, the formation of the gate structures 30, 32 could be accomplished by sequentially depositing a gate material layer (not shown) and a selective hard mask (not shown) on the substrate 12, conducting a pattern transfer process by using a patterned resist (not shown) as mask to remove part of the gate material layer and even part of the gate dielectric layer 28, and then stripping the patterned resist to form gate structures 30, 32 or gate electrodes made of patterned gate material layer on the substrate 12, in which sidewalls of the each of the gate structures 30, 32 and sidewalls of the gate dielectric layer 28 could be aligned or not aligned. In this embodiment, the gate material layer or the gate structures 30, 32 could include polysilicon, but not limited thereto.

It should be noted that even though the two gate structures 30, 32 if viewed from a cross-section perspective are disposed adjacent to two sides of the gate dielectric layer 28, the two gate structures 30, 32 if viewed under a top view perspective are in fact a single structure formed monolithically as the two gate structures 30, 32 under the top view perspective would constitute a ring. Moreover, instead of disposing two gate structures 30, 32 on the substrate 12 in this embodiment, according to other embodiment of the present invention, it would also be desirable to only form a single gate structure on the gate dielectric layer 28 during patterning of the gate material layer such that the single gate structure covers the gate dielectric layer 28 entirely. In this instance, sidewalls of the single gate structure could align or not align with left and right sidewalls of the gate dielectric layer 28, which are all within the scope of the present invention.

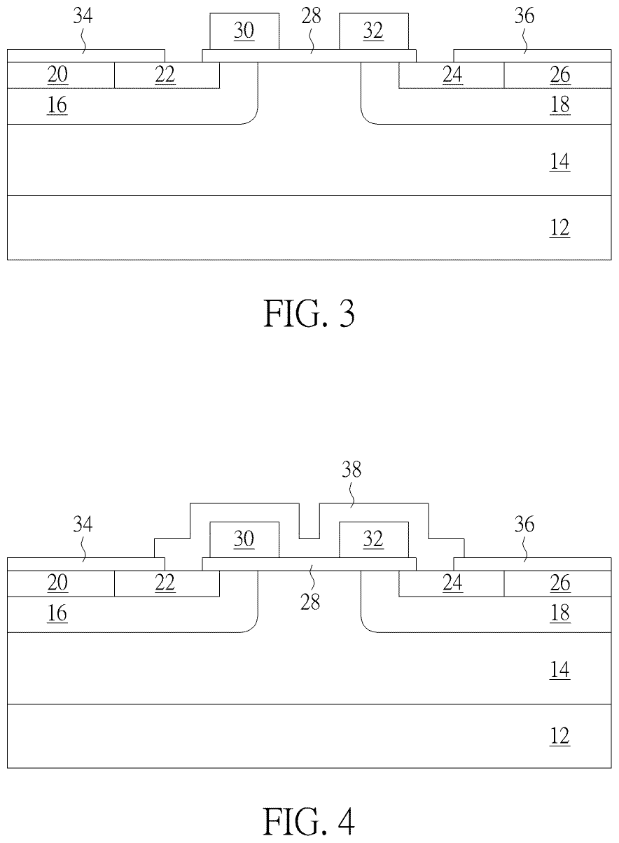

Next, as shown in FIG. 3, a first source electrode 34 is formed adjacent to one side such as left side of the gate structures 30, 32 and a second source electrode 36 is formed adjacent to another side such as right side of the gate structures 30, 32. According to an embodiment of the present invention, the formation of the first source electrode 30 and second source electrode 32 could be accomplished by depositing a metal layer (not shown) on the substrate 12 to cover the gate structures 30, 32 and then removing part of the metal layer through a photo-etching process so that the remaining patterned metal layers are disposed adjacent to two sides of the gate structures 30, 32 to form the first source electrode 34 and second source electrode 36.

Preferably, the first source electrode 34 covers or overlaps all the first doped region 20 and part of the second doped region 22, the second source electrode 36 covers part of the third doped region 24 and all the fourth doped region 26, bottom surfaces of the first source electrode 34 and second source electrode 36 are even with the bottom surface of the gate dielectric layer 28, and top surfaces of the first source electrode 34 and second source electrode 36 could be slightly lower than, even with, or higher than the top surface of the gate dielectric layer 28 but lower than the top surface of the gate structures 30, 32. In this embodiment, the first source electrode 34 and second source electrode 36 could include conductive material or metal material such as aluminum (Al), titanium (Ti), or titanium nitride (TiN).

Next, as shown in FIG. 4, a dielectric layer 38 is formed on the gate structures 30, 32 and the substrate 12 and then a photo-etching process is conducted to remove part of the dielectric layer 38 so that the remaining dielectric layer 38 covers the gate structures 30, 32, the gate dielectric layer 28 between the gate structures 30, 32, and even part of the first source electrode 34 and part of the second source electrode 36. According to an embodiment of the present invention, the dielectric layer 38 is conformally formed on the top surfaces and sidewalls of the gate structures 30, 32 as the dielectric layer 38 is preferably made of silicon nitride (SiN). Nevertheless, according to other embodiment of the present invention, the dielectric layer 38 could also include other dielectric material such as silicon oxide or silicon oxynitride (SiON).

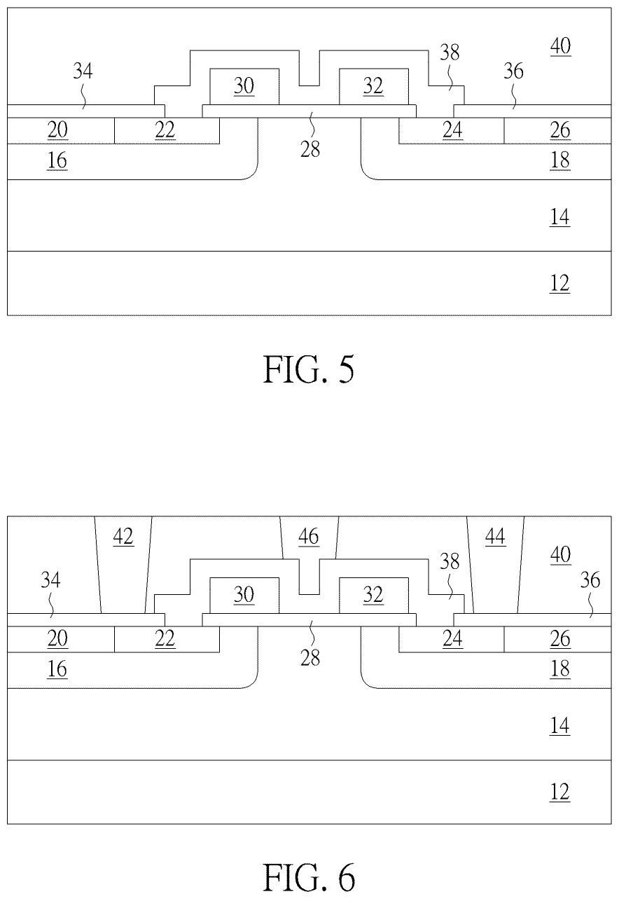

Next, as shown in FIG. 5, an interlayer dielectric (ILD) layer 40 is formed on the substrate 12 to cover the dielectric layer 38, the first source electrode 34, and the second source electrode 36. In this embodiment, the ILD layer 40 could include silicon oxide such as tetraethyl orthosilicate (TEOS), but not limited thereto.

Next, as shown in FIG. 6, a plurality of contact plugs such as a first contact plug 42 is formed on the first source electrode 34, a second contact plug 44 is formed on the second source electrode 36, and a third contact plug 46 is formed on the dielectric layer 38. In this embodiment, the formation of contact plugs could be accomplished by first using a photo-etching process to remove part of the ILD layer 40 to form contact holes (not shown) exposing the first source electrode 34, the second source electrode 36, and the surface of the dielectric layer 38, and then depositing a barrier layer (not shown) and a metal layer into the contact holes to fill the contact holes completely. A planarizing process such as chemical mechanical polishing (CMP) is then conducted to remove part of the metal layer, part of the barrier layer, and even part of the ILD layer 40 to form the first contact plug 42, the second contact plug 44, and the third contact plug 46 in the contact holes, in which the top surfaces of the first contact plug 42, the second contact plug 44, and the third contact plug 46 are even with the top surface of the ILD layer 40. In this embodiment, the barrier layer is selected from the group consisting of Ti, Ta, TiN, TaN, and WN, and the metal layer is selected from the group consisting of Al, Ti, Ta, W, Nb, Mo, and Cu.

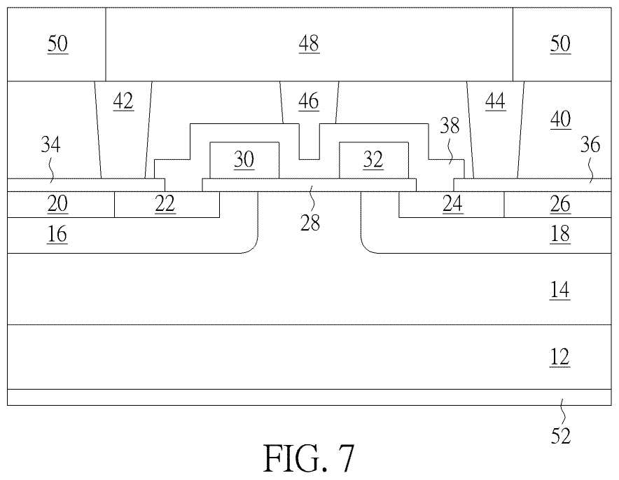

Next, as shown in FIG. 7, a field plate 48 is formed on the ILD layer 40, the first contact plug 42, the second contact plug 44, and the third contact plug 46. In this embodiment, the formation of the field plate 48 could be accomplished by first forming an inter-metal dielectric (IMD) layer 50 on the ILD layer 40 and then conducting a pattern transfer or damascene process by using patterned mask to remove part of the IMD layer 50 for forming an opening (not shown) exposing the ILD layer 40, the first contact plug 42, the second contact plug 44, and the third contact plug 46 underneath. Next, conductive material such as tungsten (W) is deposited in the opening, and then a planarizing process such as CMP is conducted to remove part of the conductive material for forming a field plate 48 in the opening for electrically connecting or directly contacting the first contact plug 42, the second contact plug 44, and the third contact plug 48. Preferably, the top surface of the field plate 48 is even with the top surface of the IMD layer 50 while left and right sidewalls of the field plate 48 could be aligned with or not aligned with sidewalls of the first contact plug 42 and second contact plug 44.

It should be noted that even though the field plate 48 is made of W, according to other embodiment of the present invention, the field plate 48 could also include a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP), which is also within the scope of the present invention. Moreover, the IMD layer 50 could include an ultra low-k (ULK) dielectric layer including but not limited to for example porous material such as silicon oxycarbide (SiOC) or SiOCH.

Next, the substrate 12 could be reversed and a deposition process is conducted to form a metal layer on the backside or bottom surface of the substrate 12 serving as a drain electrode 52. In this embodiment, the drain electrode 52 and the first source electrode 34 or second source electrode 36 could include same material or different material. For instance, the drain electrode 52 could include conductive material or metal such as Al, Ti, or TiN. This completes the fabrication of a semiconductor device or SiC MOSFET.

Overall, the present invention discloses a SiC MOSFET and fabrication method thereof, which first forms gate structures 30, 32, a first source electrode 34, a second source electrode 36, and a dielectric layer 38 on a substrate and then forms a first contact plug 42, a second contact plug 44, and a third contact plug 48 connecting the first source electrode 34, the second source electrode 36, and the dielectric layer 38 respectively. Next, a field plate 48 is formed to directly contact the first contact plug 42, the second contact plug 44, and the third contact plug 46 at the same time. According to a preferred embodiment of the present invention, the placement and combination of the field plate and aforementioned contact plugs could improve overall balance and stability of the SiC MOSFET significantly.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
forming a gate structure on a substrate;
forming a first source electrode adjacent to one side of the gate structure;
forming a first contact plug on the first source electrode;
forming a field plate on the first contact plug; and
forming a drain electrode on a backside of the substrate.

2. The method of claim 1, further comprising:
forming a drift region in the substrate;
forming a first well region adjacent to one side of the gate structure;
forming a second well region adjacent to another side of the gate structure;
forming a first doped region and a second doped region adjacent to one side of the gate structure;
forming a third doped region and a fourth doped region adjacent to another side of the gate structure;
forming a gate dielectric layer on the substrate;
forming the gate structure on the gate dielectric layer;
forming the first source electrode adjacent to one side of the gate structure;
forming a second source electrode adjacent to another side of the gate structure;
forming a dielectric layer on the gate structure;
forming an interlayer dielectric (ILD) layer on the dielectric layer;
forming the first contact plug on the first source electrode;
forming a second contact plug on the second source electrode; and
forming the field plate on the first contact plug and the second contact plug.

3. The method of claim 2, wherein the drift region and the first well region comprise different conductive type.

4. The method of claim 2, wherein the first doped region and the second doped region comprise different conductive type.

5. The method of claim 2, wherein the third doped region and the fourth doped region comprise different conductive type.

6. The method of claim 2, wherein the gate structure comprises:
a first gate structure adjacent to the second doped region; and
a second gate structure adjacent to the third doped region.

7. The method of claim 2, further comprising forming the gate dielectric layer between the second doped region and the third doped region.

8. The method of claim 2, further comprising:
forming a third contact plug on the dielectric layer; and
forming the field plate on the first contact plug, the second contact plug, and the third contact plug.

9. The method of claim 8, wherein top surfaces of the first contact plug, the second contact plug, and the third contact plug are coplanar.

10. A semiconductor device, comprising:
a gate structure on a substrate;
a first source electrode adjacent to one side of the gate structure;
a first contact plug on the first source electrode;
a field plate on the first contact plug; and
a drain electrode on a backside of the substrate.

11. The semiconductor device of claim 10, further comprising:
a drift region in the substrate;
a first well region adjacent to one side of the gate structure;
a second well region adjacent to another side of the gate structure;
a first doped region and a second doped region adjacent to one side of the gate structure;
a third doped region and a fourth doped region adjacent to another side of the gate structure;
a gate dielectric layer on the substrate;
the gate structure on the gate dielectric layer;
the first source electrode adjacent to one side of the gate structure;
a second source electrode adjacent to another side of the gate structure;
a dielectric layer on the gate structure;
an interlayer dielectric (ILD) layer on the dielectric layer;
the first contact plug on the first source electrode;
a second contact plug on the second source electrode; and
the field plate on the first contact plug and the second contact plug.

12. The semiconductor device of claim 11, wherein the drift region and the first well region comprise different conductive type.

13. The semiconductor device of claim 11, wherein the first doped region and the second doped region comprise different conductive type.

14. The semiconductor device of claim 11, wherein the third doped region and the fourth doped region comprise different conductive type.

15. The semiconductor device of claim 11, wherein the gate structure comprises:
a first gate structure adjacent to the second doped region; and
a second gate structure adjacent to the third doped region.

16. The semiconductor device of claim 11, wherein the gate dielectric layer is between the second doped region and the third doped region.

17. The semiconductor device of claim 11, further comprising:
a third contact plug on the dielectric layer; and
the field plate on the first contact plug, the second contact plug, and the third contact plug.

18. The semiconductor device of claim 17, wherein top surfaces of the first contact plug, the second contact plug, and the third contact plug are coplanar.
